(19) United States
(12) Patent Application Publication
(10) Pub. No.: US 2025/0126836 A1
(43) Pub. Date: Apr. 17, 2025

(54) SOURCE/DRAIN STRUCTURE DOPANT CLUSTER DESIGN

(71) Applicant: Taiwan Semiconductor Manufacturing Company. Ltd., Hsinchu (TW)

(72) Inventors: Yan-Ting LIN, Hsinchu (TW); Chien-I Kuo, Zhubei (TW); Ming-Hua Yu, Hsinchu (TW); Chii-Horng Li, Zhubei (TW)

(73) Assignee: Taiwan Semiconductor Manufacturing Company. Ltd., Hsinchu (TW)

(21) Appl. No.: 18/404,515

(22) Filed: Jan. 4, 2024

Related U.S. Application Data
(60) Provisional application No. 63/590,143, filed on Oct. 13, 2023.

(51) Int. Cl. H01L 29/417; H01L 21/8238; H01L 27/092; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 84/0167; H10D 84/038; H10D 84/85

(57) ABSTRACT

The present disclosure describes a semiconductor device having a source/drain structure with a dopant cluster. The semiconductor device includes a channel structure on a substrate and a source/drain structure on the substrate and adjacent to the channel structure. The source/drain structure includes a first epitaxial layer on the substrate, a second epitaxial layer on the first epitaxial layer and sidewalls of the channel structure, and a third epitaxial layer on the second epitaxial layer. The second epitaxial layer includes a cluster of a dopant extending along a direction of the channel structure.

### CROSS-REFERENCE TO RELATED APPLICATION

This application claims the benefit of U.S. Provisional Patent Application No. 63/590,143, titled “Nanosheet P-Type Epitaxy Layer Design,” filed Oct. 13, 2023, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a source/drain structure with a dopant cluster, in accordance with some embodiments.

FIGS. 2A and 2B illustrate cross-sectional views of a semiconductor device having a source/drain structure with a dopant cluster, in accordance with some embodiments.

FIG. 3 illustrates a cross-sectional view of a semiconductor device having a source/drain structure with horizontal and slanted dopant clusters, in accordance with some embodiments.

FIGS. 4A-4D illustrate various shapes of dopant clusters in a source/drain structure, in accordance with some embodiments.

FIGS. 5A-5C illustrate various shapes of channel structures in a semiconductor device, in accordance with some embodiments.

FIG. 6 is a flow diagram of a method for fabricating a semiconductor device having a source/drain structure with a dopant cluster, in accordance with some embodiments.

FIGS. 7-22B illustrate isometric and cross-sectional views of a semiconductor device having a source/drain structure with a dopant cluster at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., +1%, +2%, +3%, +4%, +5%, +10%, +20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, nanostructure transistors can provide improved device performance with a channel in a stacked nanosheet/nanowire configuration. The nanostructure transistors can include finFETs, gate-all-around field effect transistors (GAA FETs), nanosheet transistors, nanowire transistors, multi-bridge channel transistors, nano-ribbon transistors, and other similar structured transistors. However, during the sheet formation process of the channel, source/drain (S/D) structures of the nanostructure transistors can also be etched and gate-S/D short defects can be formed subsequently. The gate-S/D short defects can lead to device failure and yield loss.

Various embodiments in the present disclosure provide example methods for forming a S/D structure having a dopant cluster in a semiconductor device (e.g., a nanostructure transistor) and/or other semiconductor devices in an integrated circuit (IC). In some embodiments, a channel structure can be formed on a substrate. A S/D structure can be formed on the substrate and adjacent to the channel structure. In some embodiments, the S/D structure can include a first epitaxial layer on the substrate, a second epitaxial layer on the first epitaxial layer and sidewalls of the channel structure, and a third epitaxial layer on the second epitaxial layer. In some embodiments, the second epitaxial layer can include a cluster of a dopant extending along a direction of the channel structure. In some embodiments, a first concentration of the dopant in the cluster can be more than about ten times greater than a concentration of the dopant in the second epitaxial layer. In some embodiments, the cluster of the dopant can extend along an intersection of (111) growth planes of the second epitaxial layer. In some embodiments, the second epitaxial layer can include an additional cluster of the dopant along the (111) growth planes of the second epitaxial layer. The clusters of the dopant can reduce etching damage to the S/D structure, reduce gate-S/D short defects, and improve device performance and yield.

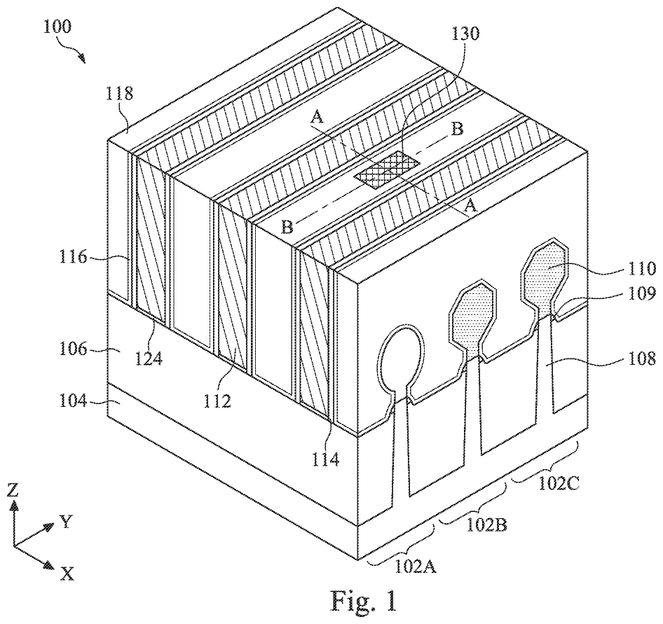

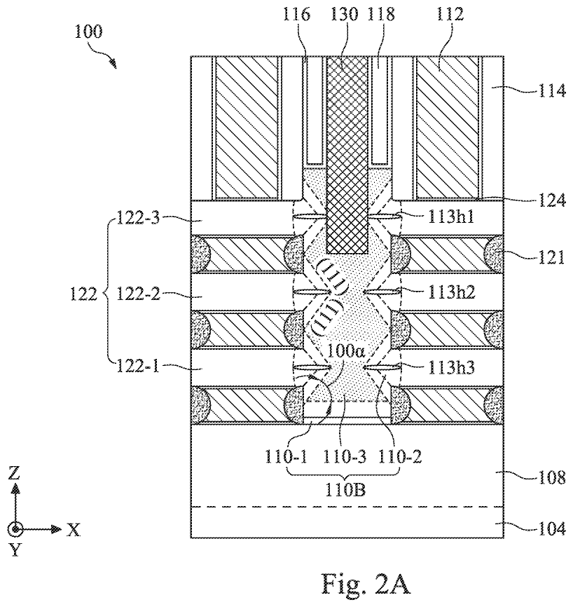

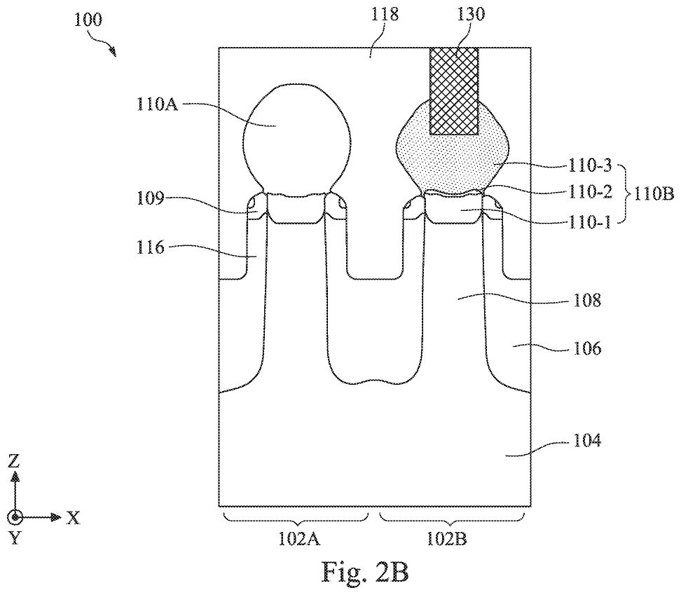

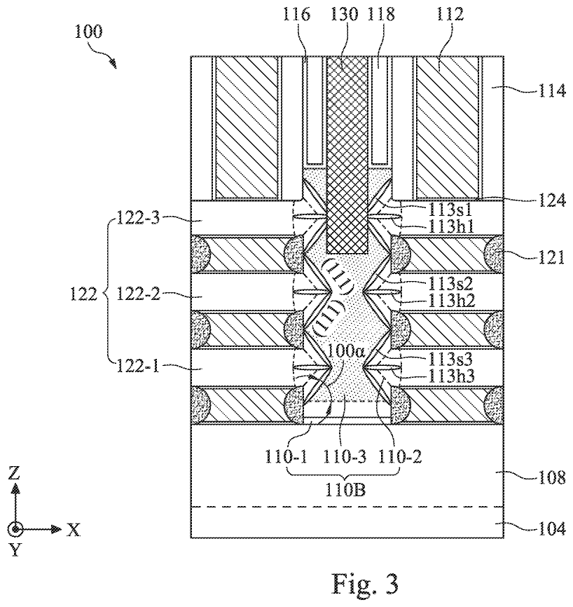

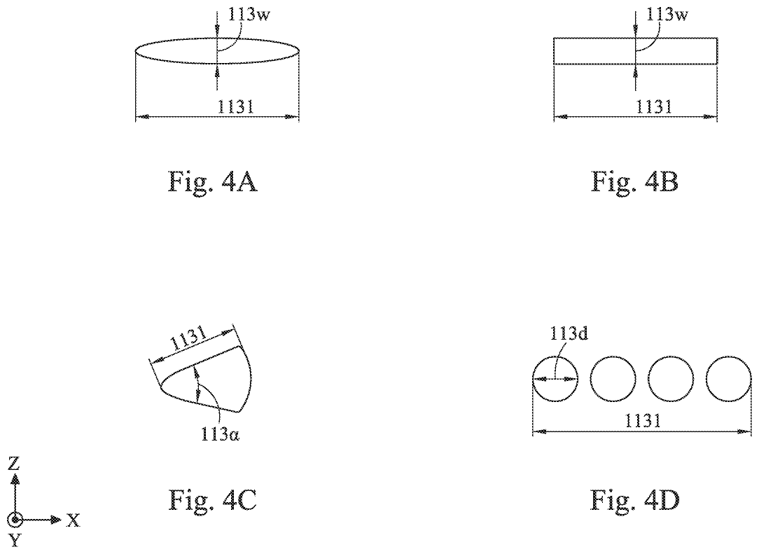

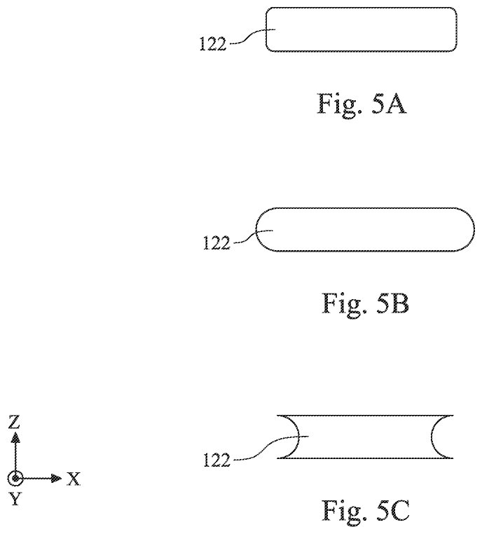

FIG. 1 illustrates an isometric view of a semiconductor device 100 having a source/drain structure with a dopant cluster, in accordance with some embodiments. FIGS. 2A and 2B illustrate partial cross-sectional views of semiconductor device 100 across line A-A and line B-B shown in FIG. 1, respectively, in accordance with some embodiments. FIG. 3 illustrates a partial cross-sectional view of semiconductor device 100 having a source/drain structure with horizontal and slanted dopant clusters, in accordance with some embodiments. FIGS. 4A-4D illustrate various shapes of dopant clusters in a source/drain structure, in accordance with some embodiments. FIGS. 5A-5C illustrate various shapes of channel structures in semiconductor device 100, in accordance with some embodiments.

In some embodiments, semiconductor device 100 can include transistors 102A-102C, as shown in FIG. 1. In some embodiments, transistors 102A-102C can include nanostructure transistors. The nanostructure transistors can include finFETs, GAA FETs, nanosheet transistors, nanowire transistors, multi-bridge channel transistors, nano-ribbon transistors, and other similar structured transistors. The nanostructure transistors can provide a channel in a stacked nanosheet/nanowire configuration. In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. In some embodiments, transistor 102A can be an NFET and transistors 102B and 102C can be PFETs. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1-5, semiconductor device 100 having transistors 102A-102C can be formed on a substrate 104 and can be isolated by shallow trench isolation (STI) regions 106. Each of transistors 102A-102C can include fin structures 108, sidewall spacers 109, gate dielectric layer 124, gate structures 112, gate spacers 114, inner spacers 121, S/D structures 110, etch stop layer (ESL) 116, and interlayer dielectric (ILD) layer 118. In some embodiments, as shown in FIG. 2, transistors 102A-102C can have nanostructures 122-1, 122-2, and 122-3 (collectively referred to as “nanostructures 122”) on fin structures 108.

Referring to FIGS. 1-3, substrate 104 can include a semiconductor material, such as silicon. In some embodiments, substrate 104 includes a crystalline silicon substrate (e.g., silicon wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1-3, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1-3, nanostructures 122 and fin structures 108 can extend along an X-axis for transistors 102A-102C. In some embodiments, nanostructures 122 and fin structures 108 can be disposed on substrate 104. Nanostructures 122 can include a stack of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102C. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIGS. 2A and 3, nanostructures 122 under gate structures 112 can form channel regions of semiconductor device 100 and represent current carrying channel structures of semiconductor device 100. Though three layers of nanostructures 122 are shown in FIGS. 2A and 3, transistors 102A-102C can have any number of nanostructures 122.

In some embodiments, nanostructures 122 can have a thickness along a Z-axis ranging from about 5 nm to about 8 nm. In some embodiments, nanostructures 122 can have a width along a Y-axis ranging from about 15 nm to about 50 nm. In some embodiments, a spacing between adjacent nanostructures 122 along a Z-axis can range from about 8 nm to about 12 nm. In some embodiments, as shown in FIG. 5A, nanostructures 122 can have square end portions. In some embodiments, as shown in FIG. 5B, nanostructures 122 can have convex end portions. In some embodiments, as shown in FIG. 5C, nanostructures 122 can have concave end portions.

Referring to FIGS. 1-3, gate dielectric layer 124 can be formed on nanostructures 122, fin structures 108, and STI regions 106. In some embodiments, gate dielectric layer 124 can be multi-layered structures and can include an interfacial layer and a high-k dielectric layer. In some embodiments, gate dielectric layer 124 can include no interfacial layer and a high-k dielectric layer in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 1-3, gate structures 112 can be disposed on gate dielectric layer 124. In some embodiments, gate structures 112 can include one or more work function metal layers and a metal fill. The one or more work function metal layers can include work function metals to tune the threshold voltage (Vₜ) of transistors 102A-102C. In some embodiments, gate structures 112 for NFET and PFET devices can have substantially the same work-function metal. In some embodiments, gate structures 112 for NFET and PFET devices can have different work-function metals. In some embodiments, as shown in FIGS. 2A and 3, each of nanostructures 122 can be wrapped around by gate structures 112, for which gate structures 112 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1-3, gate spacers 114 can be disposed on sidewalls of gate structures 112 and in contact with gate dielectric layer 124, according to some embodiments. Sidewall spacers 109 can be disposed on sidewalls of fin structures 108. Inner spacers 121 can be disposed adjacent to end portions of nanostructures 122 and between S/D structures 110 and gate structures 112. Gate spacers 114, sidewall spacers 109, and inner spacers 121 can include insulating materials, such as silicon oxide, silicon nitride, silicon oxynitride, silicon carbonitride, silicon oxycarbide, silicon oxycarbonitride, a low-k material, and a combination thereof. In some embodiments, gate spacers 114, sidewall spacers 109, and inner spacers 121 can include the same insulating material. In some embodiments, gate spacers 114, sidewall spacers 109, and inner spacers 121 can include different insulating materials. In some embodiments, gate spacers 114, sidewall spacers 109, and inner spacers 121 can include a single layer or a stack of insulating layers. In some embodiments, gate spacers 114, sidewall spacers 109, and inner spacers 121 can have a low-k material with a dielectric constant less than about 3.9 (e.g., about 3.5, about 3.0, or about 2.8).

S/D structures 110 can be disposed on fin structures 108 and on opposing sides of gate structures 112. S/D structures 110 can function as S/D regions of transistors 102A-102C. In some embodiments, S/D structures 110 can have any geometric shape, such as a polygon, a cone, a diamond, an ellipsis, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions under gate structures 112. Since the lattice constant of such epitaxially-grown semiconductor material is different from the material of substrate 104, the channel regions are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. For n-type in-situ doping, n-type doping precursors, such as phosphine, arsine, and other n-type doping precursors, can be used. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. For p-type in-situ doping, p-type doping precursors, such as diborane (B₂H₆), boron trifluoride (BF₃), and other p-type doping precursors, can be used.

In some embodiments, S/D structures 110 can include one or more epitaxial layers, where each epitaxial layer can have different compositions. In some embodiments, as shown in FIGS. 1-3, S/D structures 110 can include epitaxially-grown first epitaxial layers 110-1, second epitaxial layers 110-2, and third epitaxial layers 110-3. First epitaxial layers 110-1 can be epitaxially grown on partially-recessed portions of substrate 104, second epitaxial layers 110-2 can be epitaxially grown on first epitaxial layers 110-1 and sidewalls of nanostructures 122, and third epitaxial layers 110-3 can be epitaxially grown on second epitaxial layers 110-2. Though FIGS. 1-3 illustrate three epitaxial layers for S/D structures 110, S/D structures 110 can have one or more epitaxial layers and each epitaxial layer can have different compositions.

In some embodiments, each of first epitaxial layers 110-1, second epitaxial layers 110-2, and third epitaxial layers 110-3 can include Si and differ from each other based on, for example, doping concentration and/or epitaxial growth process conditions. In some embodiments, each of first epitaxial layers 110-1, second epitaxial layers 110-2, and third epitaxial layers 110-3 can include silicon germanium and differ from each other based on, for example, doping concentration, epitaxial growth process conditions, and/or relative concentration of germanium with respect to silicon. For example, the germanium atomic percent in first epitaxial layers 110-1 can be less than the germanium atomic percent in second and third epitaxial layers 110-2 and 110-3. In some embodiments, first epitaxial layers 110-1 can include silicon without germanium. In some embodiments, second epitaxial layers 110-2 can include germanium in a range from about 0 atomic percent to about 50 atomic percent, and third epitaxial layers 110-3 can include germanium in a range from about 50 atomic percent to about 80 atomic percent, with any remaining atomic percent being Si.

In some embodiments, first, second, and third epitaxial layers 110-1, 110-2, and 110-3 can have varying dopant concentration with respect to each other. For example, first epitaxial layers 110-1 can have a dopant concentration lower than the dopant concentrations of second and third epitaxial layers 110-2 and 110-3. Second epitaxial layers 110-2 can have a dopant concentration lower than the dopant concentration of third epitaxial layers 110-3. In some embodiments, first epitaxial layers 110-1 can be undoped. Second epitaxial layers 110-2 can be doped with boron having a concentration less than about 5×10²⁰ atoms/cm³, for example, from about 1×10²⁰ to about 5×10²⁰ atoms/cm³. Third epitaxial layers 110-3 can be doped with boron having a concentration in a range from about 5×10²⁰ to about 2×10²¹ atoms/cm³. Higher dopant concentration in third epitaxial layers 110-3 can reduce contact resistance between S/D structures 110 and S/D contact structures 130.

In some embodiments, second epitaxial layers 110-2 can include one or more dopant clusters. For example, as shown in FIG. 2A, second epitaxial layers 110-2 can include horizontal dopant clusters 113h1, 113h2, and 113h (collectively referred to as “horizontal dopant clusters 113h”). Horizontal dopant clusters 113h can extend along a direction of nanostructures 122 between adjacent stacks of nanostructures 122. In some embodiments, horizontal dopant clusters 113h can extend from nanostructures 122 to third epitaxial layers 110-3. In some embodiments, the dopant in second epitaxial layers 110-2 can aggregate on (111) growth planes of second epitaxial layers 110-2 and horizontal dopant clusters 113h can be formed along an intersection of the (111) growth planes. In some embodiments, an angle 110a between the (111) growth planes and a horizontal direction along nanostructures 110 can range from about 40 degrees and about 70 degrees.

In some embodiments, a concentration of the dopant in horizontal dopant clusters 113h can be more than ten times greater than the concentration of the dopant in second epitaxial layers 110-2 and the dopant on other planes (e.g., (001) planes) of second epitaxial layers 110-2. For example, horizontal dopant clusters 113h can include aggregations of boron dopant having a concentration from about 5×10²⁰ to about 5×10²¹ atoms/cm³. In some embodiments, the high dopant concentration in horizontal dopant clusters 113h can increase the etch resistance of S/D structures 110 and/or inner spacers 121 during the sheet formation process of nanostructures 122. As a result, horizontal dopant clusters 113h can reduce etching damage to S/D structures 110, reduce gate-S/D short defects, and improve device performance and yield of semiconductor device 100. If the dopant concentration in horizontal dopant clusters 113h is less than about 5×10²⁰ atoms/cm³, etching damage to S/D structures 110 may not be reduced. If the dopant concentration in horizontal dopant clusters 113h is greater than about 5×10²¹ atoms/cm³, more dopants may diffuse into nanostructures 122 and may increase device leakage current.

Referring to FIGS. 4A-4D, horizontal dopant clusters 113h can have different shapes. In some embodiments, as shown in FIG. 4A, horizontal dopant clusters 113h can have an oval shape with a length 1131 ranging from about 0 nm to about 10 nm and a width 113w ranging from about 0 nm to about 4 nm. In some embodiments, as shown in FIG. 4B, horizontal dopant clusters 113h can have a square shape with length 1131 ranging from about 0 nm to about 10 nm and width 113w ranging from about 0 nm to about 4 nm. In some embodiments, as shown in FIG. 4C, horizontal dopant clusters 113h can have a fan shape with length 1131 ranging from about 0 nm to about 10 nm and an angle 113a ranging from about 0 degree to about 60 degrees. In some embodiments, as shown in FIG. 4D, horizontal dopant clusters 113h can include a number of circles along a line with length 1131 ranging from about 0 nm to about 10 nm and a circle diameter 113d ranging from about 0 nm to about 2 nm.

In some embodiments, horizontal dopant clusters 113h adjacent to top, middle, and bottom nanostructures 122-1, 122-2, and 122-3 can have different sizes. In some embodiments, horizontal dopant clusters 113h-1 adjacent to top nanostructures 122-1 can have a greater size (e.g., width 113w and/or length 1131) than horizontal dopant clusters 113h-2 adjacent to middle nanostructures 122-2. In some embodiments, horizontal dopant clusters 113h-2 adjacent to middle nanostructures 122-2 can have a greater size (e.g., width 113w and/or length 1131) than horizontal dopant clusters 113h-3 adjacent to bottom nanostructures 122-3.

In some embodiments, as shown in FIG. 3, second epitaxial layers 110-2 can include horizontal dopant clusters 113h and slanted dopant clusters 113s1, 113s2, and 113s3 (collectively referred to as “slanted dopant clusters 113s”). In some embodiments, the dopant in second epitaxial layers 110-2 can aggregate on (111) growth planes of second epitaxial layers 110-2 and form slanted dopant clusters 113s. In some embodiments, slanted dopant clusters 113s can extend along the (111) growth planes of second epitaxial layers 110-2 and intersect with horizontal dopant clusters 113h. In some embodiments, the (111) growth planes of second epitaxial layers 110-2 can be in contact with third epitaxial layers 110-3. Accordingly, slanted dopant clusters 113s can extend along an interface between the second and third epitaxial layers 110-2 and 110-3. In some embodiments, an angle between slanted dopant clusters 113s and horizontal dopant clusters 113h can be substantially the same as angle 110α and can range from about 40 degrees to about 70 degrees. In some embodiments, slanted dopant clusters 113s can extend along the (111) growth planes to inner spacers 121 and can be in contact with inner spacers 121.

In some embodiments, a concentration of the dopant in slanted dopant clusters 113s can be more than ten times greater than the concentration of the dopant in second epitaxial layers 110-2 and the dopant on other planes (e.g., (001) planes) of second epitaxial layers 110-2. For example, slanted dopant clusters 113s can include aggregations of boron dopant having a concentration from about 5×10²⁰ to about 5×10²¹ atoms/cm³. In some embodiments, the dopant concentration in horizontal dopant clusters 113h can be greater than the dopant concentration in slanted dopant clusters 113s. In some embodiments, the high dopant concentration in both horizontal dopant clusters 113h and slanted dopant clusters 113s can further increase the etch resistance of S/D structures 110 and/or inner spacers 121 during the sheet formation process of nanostructures 122. As a result, horizontal dopant clusters 113h and slanted dopant clusters 113s can further reduce etching damage to S/D structure 110, reduce gate-S/D short defects, and improve device performance and yield of semiconductor device 100.

In some embodiments, similar to horizontal dopant clusters 113h as described above, slanted dopant clusters 113s can have different shapes and sizes as shown in FIGS. 4A-4D. In some embodiments, slanted dopant clusters 113s adjacent to top, middle, and bottom nanostructures 122-1, 122-2, and 122-3 can have different sizes, similar to horizontal dopant clusters 113h. In some embodiments, slanted dopant clusters 113s-1 adjacent to top nanostructures 122-1 can have a greater size (e.g., width 113w and/or length 1131) than slanted dopant clusters 113s-2 adjacent to middle nanostructures 122-2. In some embodiments, slanted dopant clusters 113s-2 adjacent to middle nanostructures 122-2 can have a greater size (e.g., width 113w and/or length 1131) than slanted dopant clusters 113s-3 adjacent to bottom nanostructures 122-3.

ESL 116 can be disposed on STI regions 106, S/D structures 110, and sidewalls of gate spacers 114 and sidewall spacers 109. ESL 116 can be configured to protect STI regions 106, S/D structures 110, and gate structures 112 during the formation of S/D contact structures 130 on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIGS. 1-3, semiconductor device 100 can further include S/D contact structures 130. In some embodiments, S/D contact structures 130 can be disposed on S/D structures 110. In some embodiments, S/D contact structures 130 can include a silicide layer and a metal contact. In some embodiments, the silicide layer can include a metal silicide and can provide a lower resistance interface between the metal contact and S/D structures 110. Examples of metal used for forming the metal silicide include cobalt, titanium, and nickel. In some embodiments, the metal contact can include conductive materials, such as tungsten, aluminum, and cobalt. In some embodiments, as shown in FIGS. 1-3, S/D contact structures 130 can extend into S/D structures 110 and can be in contact with horizontal dopant clusters 113h and/or slanted dopant clusters 113s. In some embodiments, the high dopant concentration in horizontal dopant clusters 113h and slanted dopant clusters 113s can further reduce the contact resistance between S/D contact structures 130 and S/D structures 110.

In some embodiments, horizontal dopant clusters 113h and slanted dopant clusters 113s can include hydrogen, chlorine, carbon, fluorine, oxygen, and/or titanium due to materials used during the process flows. For example, hydrogen and chlorine can diffuse into horizontal dopant clusters 113h and slanted dopant clusters 113s during the epitaxial growth of S/D structures with a hydrogen chloride-containing gas. Carbon and oxygen in dielectric materials can diffuse into horizontal dopant clusters 113h and slanted dopant clusters 113s during the deposition processes of ESL 116 and/or ILD layer 118. Fluorine in fluorine-based etchants can diffuse into horizontal dopant clusters 113h and slanted dopant clusters 113s during the sheet formation process of nanostructures 122. Titanium in the silicide layer can diffuse into horizontal dopant clusters 113h and slanted dopant clusters 113s during the formation of S/D contact structures.

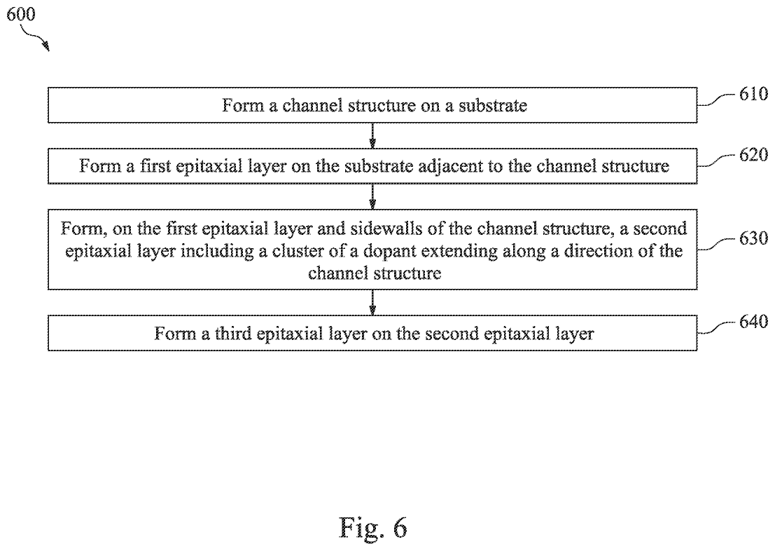

FIG. 6 is a flow diagram of a method 600 for fabricating semiconductor device 100 having a S/D structure with a dopant cluster, in accordance with some embodiments. Method 600 may not be limited to nanostructure transistor devices and can be applicable to other devices that would benefit from the S/D structure with a dopant cluster. Additional fabrication operations may be performed between various operations of method 600 and may be omitted merely for clarity and ease of description. Additional processes can be provided before, during, and/or after method 600; one or more of these additional processes are briefly described herein. Moreover, not all operations may be needed to perform the disclosure provided herein. Additionally, some of the operations may be performed simultaneously or in a different order than shown in FIG. 6. In some embodiments, one or more other operations may be performed in addition to or in place of the presently-described operations.

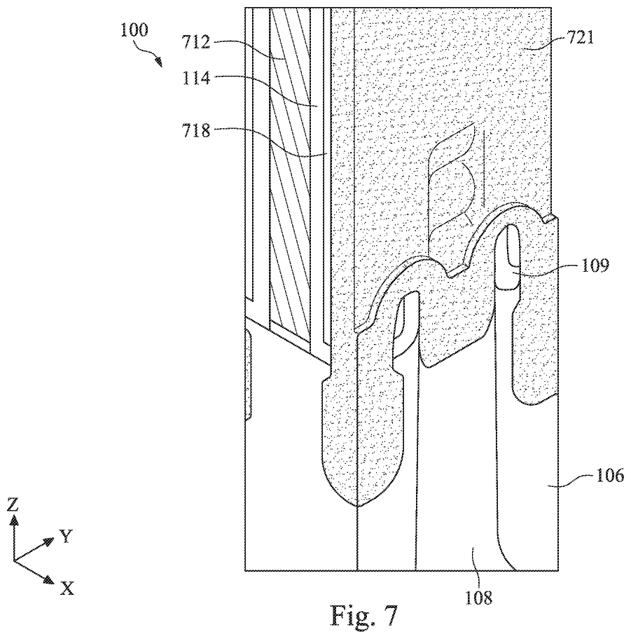

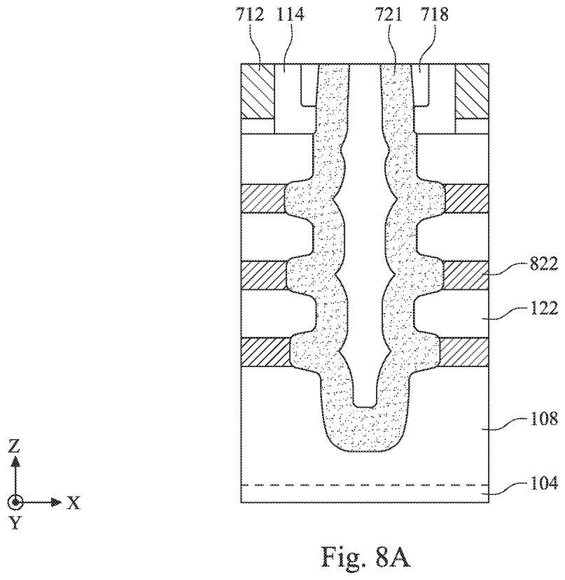

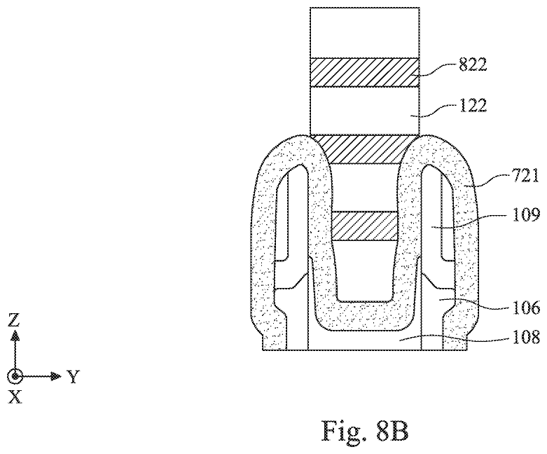

For illustrative purposes, the operations illustrated in FIG. 6 will be described with reference to the example fabrication process for fabricating semiconductor device 100 as illustrated in FIGS. 7-22B. FIGS. 7-22B illustrate partial isometric and partial cross-sectional views of semiconductor device 100 having a S/D structure with a dopant cluster at various stages of its fabrication, in accordance with some embodiments. FIGS. 7, 9, 11, 13, 15, 17, 19, and 21 illustrate partial isometric views of semiconductor device 100 at various stages of its fabrication, in accordance with some embodiments. FIGS. 8A, 10A, 12A, 14A, 16A, 18A, 20A, and 22A illustrate partial cross-sectional views of semiconductor device 100 along line A-A as shown in FIG. 1 at various stages of its fabrication, in accordance with some embodiments. FIGS. 8B, 10B, 12B, 14B, 16B, 18B, 20B, and 22B illustrate partial cross-sectional views of semiconductor device 100 along line B-B as shown in FIG. 1 at various stages of its fabrication, in accordance with some embodiments. Elements in FIGS. 7-22B with the same annotations as elements in FIGS. 1-5 are described above.

In referring to FIG. 6, method 600 begins with operation 610 and the process of forming a channel structure on a substrate. For example, as shown in FIGS. 7, 8A, and 8B, nanostructures 122 and 822 can be formed on substrate 104. In some embodiments, nanostructures 122 and 822 can be stacked in an alternate configuration. In some embodiments, nanostructures 122 and 822 can be epitaxially grown on substrate 104 and subsequently patterned to form stacks of nanostructures 122 and 822. In some embodiments, nanostructures 122 and 822 can be in the form of nanosheets, nanowires, or nano-ribbons. In some embodiments, nanostructures 122 and 822 can include semiconductor materials similar to or different from substrate 104. In some embodiments, nanostructures 122 and 822 can include different semiconductor materials. For example, nanostructures 122 can include silicon and nanostructures 822 can include silicon germanium with a germanium atomic percent from about 10% to about 40%.

Embodiments of nanostructures 122 and 822 disclosed herein may be patterned by any suitable method. For example, the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures.

The formation of nanostructures 122 can be followed by the formation of STI regions 106 between adjacent stacks of nanostructures 122 and 822, the formation of sacrificial gate structures 712 on nanostructures 122, the formation of gate spacers 114 and 718 on sidewalls of sacrificial gate structures 712, the recess of nanostructures 122 and 822, and the deposition of inner spacer layer 721 in the recess, as shown in FIGS. 7, 8A, and 8B. These processes are not described in detail for clarity.

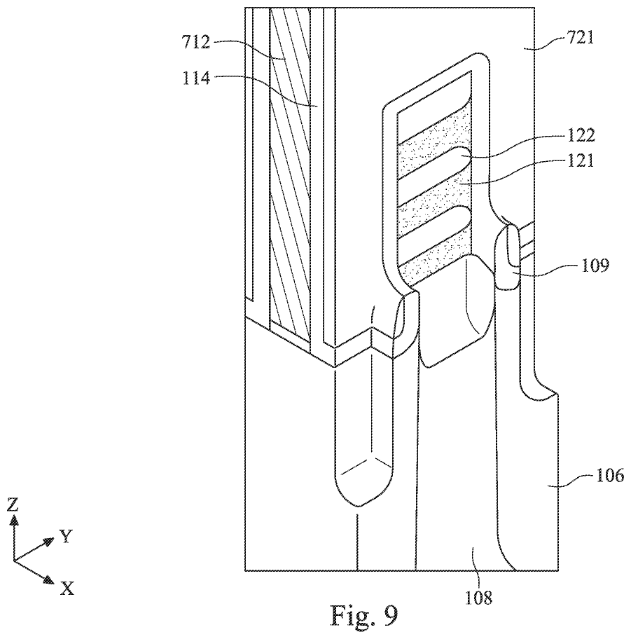

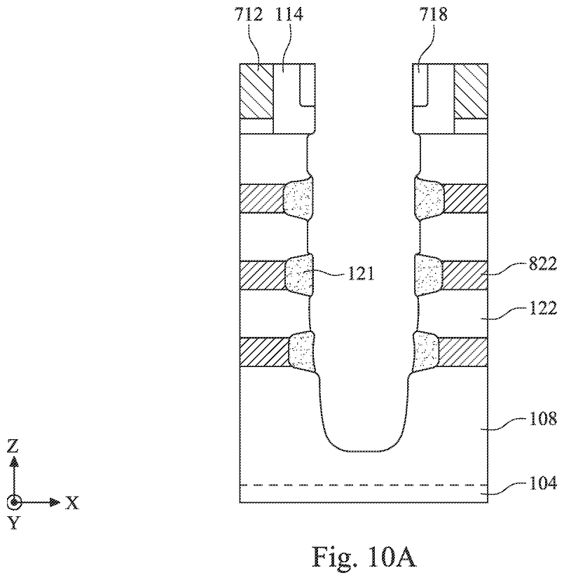

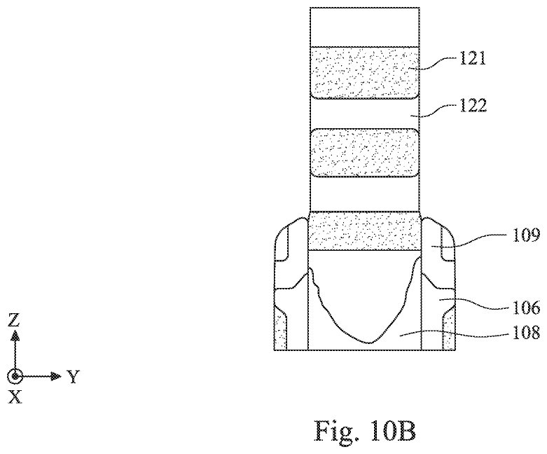

In some embodiments, the deposition of inner spacer layer 721 can be followed by an etching process to form inner spacers 121, as shown in FIGS. 9, 10A, and 10B. In some embodiments, the etching process can be a directional etching process to remove inner spacer layer 721 on sidewalls of nanostructures 122 and top surfaces of fin structures 108.

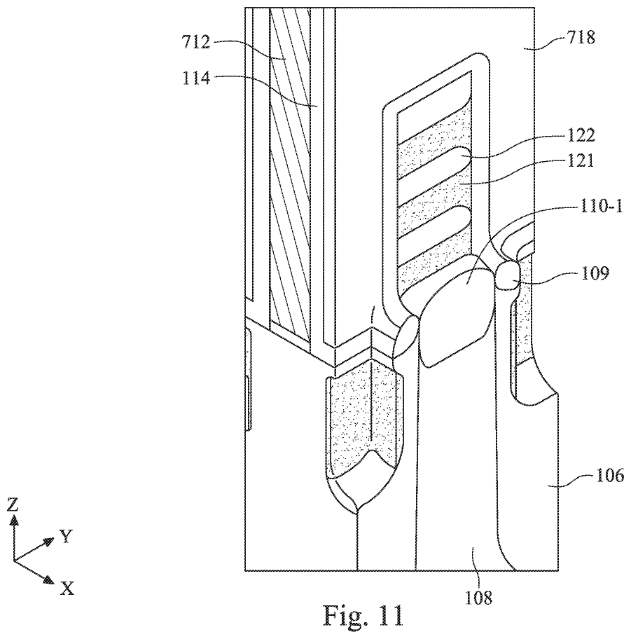

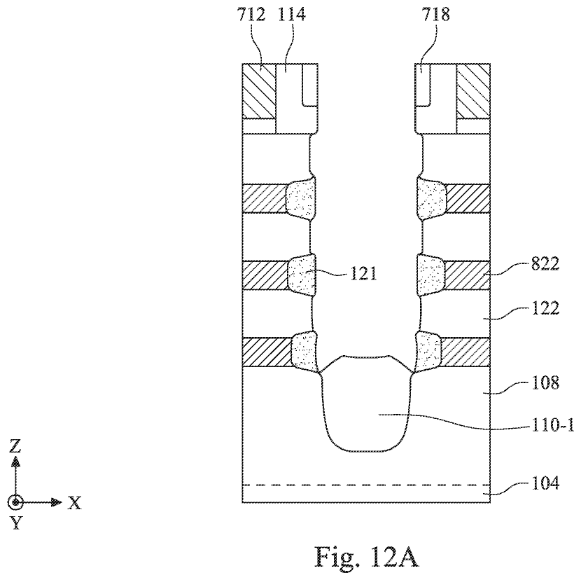

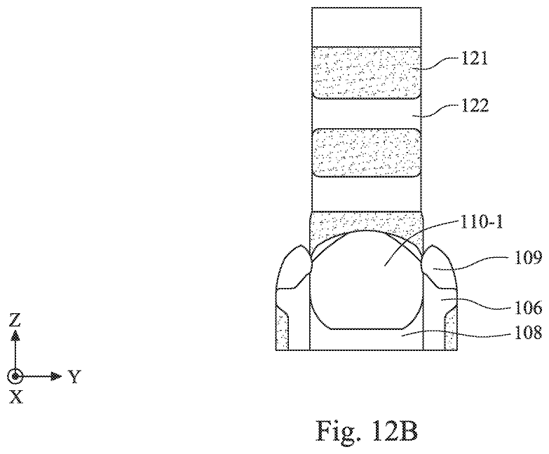

Referring to FIG. 6, in operation 620, a first epitaxial layer is formed on the substrate adjacent to the channel structure. For example, as shown in FIGS. 11, 12A, and 12B, first epitaxial layer 110-1 can be formed on substrate 104 adjacent to nanostructures 122. In some embodiments, first epitaxial layer 110-1 can be epitaxially grown on fin structures 108 over substrate 104 with a bottom-up growth method. In some embodiments, first epitaxial layer 110-1 can include intrinsic silicon without a dopant. In some embodiments, first epitaxial layer 110-1 can be formed on fin structures 108 of transistors 102A-102C. In some embodiments, first epitaxial layer 110-1 can be formed on n-type transistors with p-type transistors blocked by a hard mask layer.

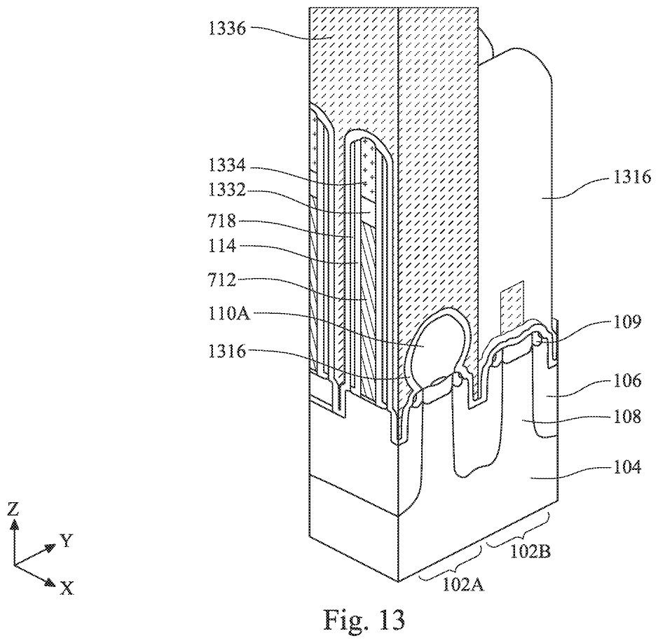

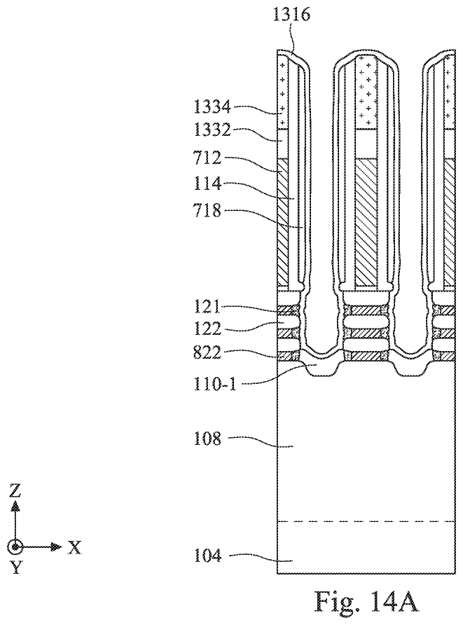

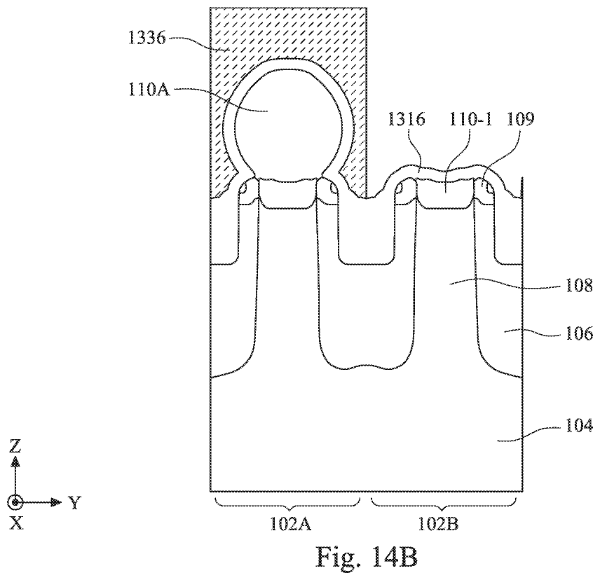

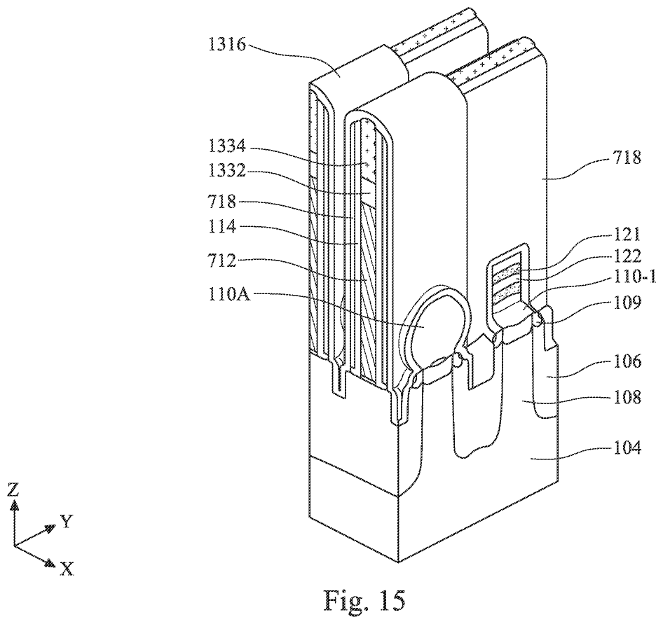

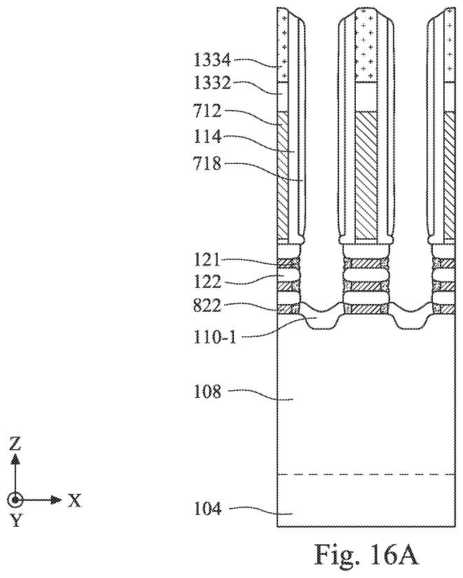

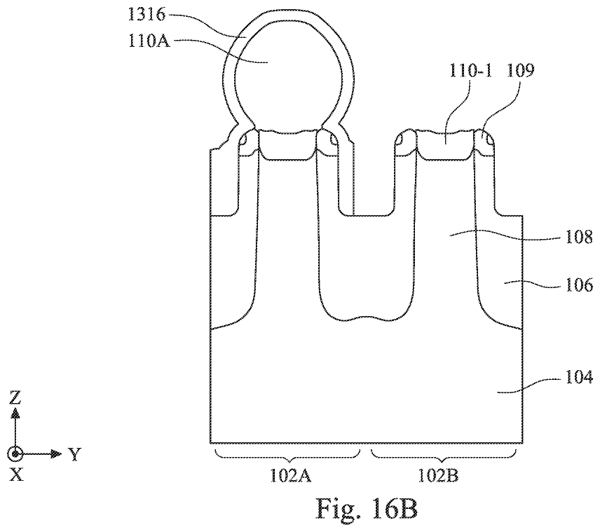

In some embodiments, n-type S/D structures (e.g., S/D structures 110A) can be formed before p-type S/D structures (e.g., S/D structures 110B). For example, as shown in FIGS. 13, 14A, and 14B, n-type S/D structures 110A can be formed on fin structures 108 covered with dielectric layer 1316. Hard mask layers 1332 and 1334 can be formed on sacrificial gate structures 712. Hard mask layer 1336 can be formed on transistor 102A and patterned to expose transistor 102B for epitaxial growth of S/D structures 110B. In some embodiments, dielectric layer 1316 on transistor 102B can be removed by an etching process. A pre-clean process can clean any residual dielectric material on first epitaxial layer 110-1. After the etching and pre-clean processes, first epitaxial layer 110-1 of transistor 102B can be exposed for epitaxial growth of additional layers, as shown in FIGS. 15, 16A, and 16B.

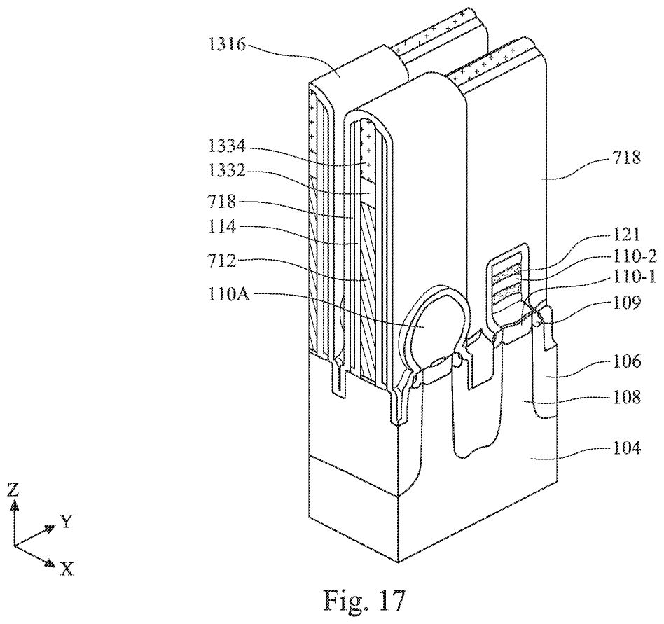

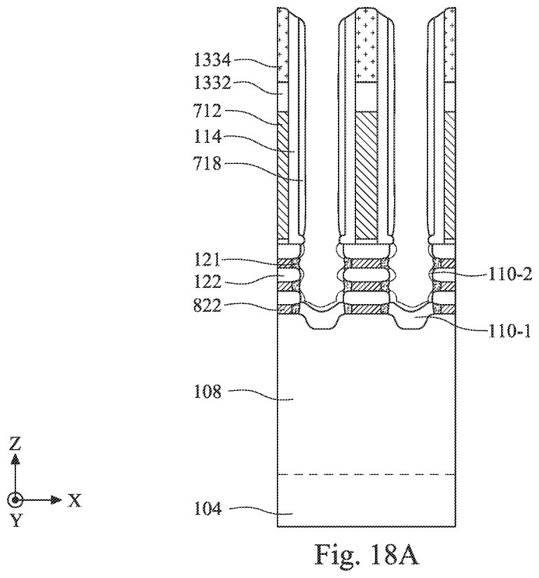

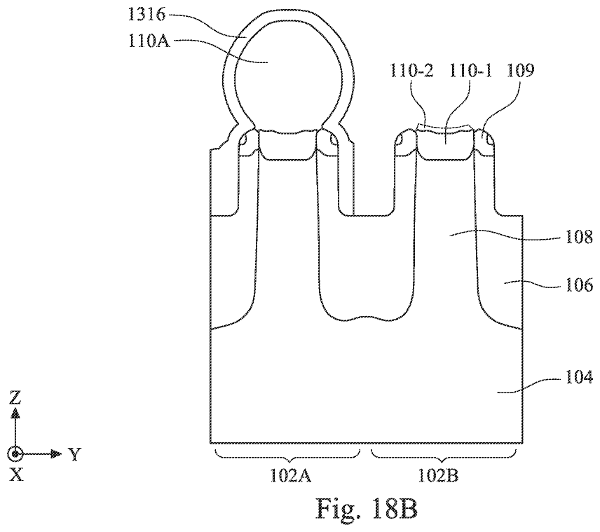

Referring to FIG. 6, in operation 630, a second epitaxial layer is formed on the first epitaxial layer and sidewalls of the channel structure. The second epitaxial layer includes a cluster of a dopant extending along a direction of the channel structure. For example, as shown in FIGS. 17, 18A, and 18B, second epitaxial layer 110-2 can be formed on first epitaxial layer 110-1 and sidewalls of nanostructures 122. In some embodiments, second epitaxial layer 110-2 can include horizontal dopant clusters 113h along a direction of nanostructures 122, as shown in FIG. 2A. In some embodiments, second epitaxial layer 110-2 can include horizontal dopant clusters 113h along a direction of nanostructures 122 and slanted dopant clusters 113s along (111) growth planes of second epitaxial layer 110-2, as shown in FIG. 3. In some embodiments, horizontal dopant clusters 113h and slanted dopant clusters 113s in second epitaxial layer 110-2 can include aggregations of boron.

In some embodiments, during the epitaxial growth of second epitaxial layer 110-2, a dopant-containing precursor can be controlled at a substantially constant flow rate to form a peak value of dopant concentration greater than about 5×10²⁰ atoms/cm³. In some embodiments, horizontal dopant clusters 113h and/or slanted dopant clusters 113s can be formed in second epitaxial layer 110-2 during the epitaxial growth. In some embodiments, the dopant in second epitaxial layers 110-2 can aggregate on (111) growth planes of second epitaxial layers 110-2 and horizontal dopant clusters 113h can be formed along an intersection of the (111) growth planes. In some embodiments, the dopant in second epitaxial layers 110-2 can aggregate on (111) growth planes of second epitaxial layers 110-2 and form slanted dopant clusters 113s. In some embodiments, an angle between slanted dopant clusters 113s and horizontal dopant clusters 113h can range from about 40 degrees to about 70 degrees. In some embodiments, slanted dopant clusters 113s can extend along the (111) growth planes to inner spacers 121 and can be in contact with inner spacers 121.

In some embodiments, second epitaxial layer 110-2 can include silicon germanium with a germanium concentration from about 0 atomic percent to about 50 atomic percent, with any remaining atomic percent being Si. In some embodiments, horizontal dopant clusters 113h and slanted dopant clusters 113s can include aggregations of boron having a concentration from about 5×10²⁰ to about 5×10²¹ atoms/cm³. In some embodiments, second epitaxial layers 110-2 can be doped during the epitaxial growth with boron having a concentration less than about 5×10²⁰ atoms/cm³, for example, from about 1×10²⁰ atoms/cm³ to about 5×10²⁰ atoms/cm³. In some embodiments, a concentration of the dopant in horizontal dopant clusters 113h and/or slanted dopant clusters 113s can be more than ten times greater than the concentration of the dopant in second epitaxial layers 110-2 and the dopant on other planes (e.g., (001) planes) of second epitaxial layers 110-2. In some embodiments, a concentration of the dopant in horizontal dopant clusters 113h can be more than a concentration of the dopant slanted dopant clusters 113s.

In some embodiments, the high dopant concentration in horizontal dopant clusters 113h and/or slanted dopant clusters 113s can increase the etch resistance of S/D structures 110 and/or inner spacers 121 during the sheet formation process of nanostructures 122. As a result, horizontal dopant clusters 113h and slanted dopant clusters 113s can reduce etching damage to S/D structures 110, reduce gate-S/D short defects, and improve device performance and yield of semiconductor device 100. If the dopant concentration in horizontal dopant clusters 113h and/or slanted dopant clusters 113s is less than about 5×10²⁰ atoms/cm³, etching damage to S/D structures 110 may not be reduced. If the dopant concentration in horizontal dopant clusters 113h and/or slanted dopant clusters 113s is greater than about 5×10²¹ atoms/cm³, more dopants may diffuse into nanostructures 122 and may increase device leakage current.

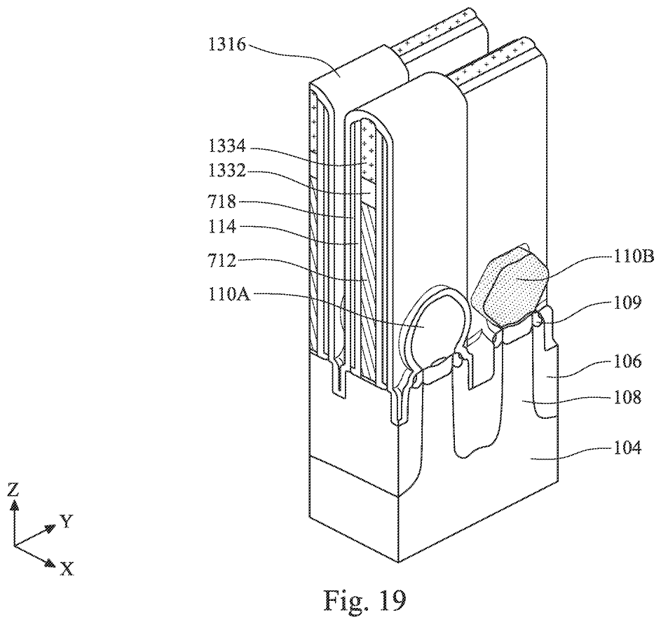

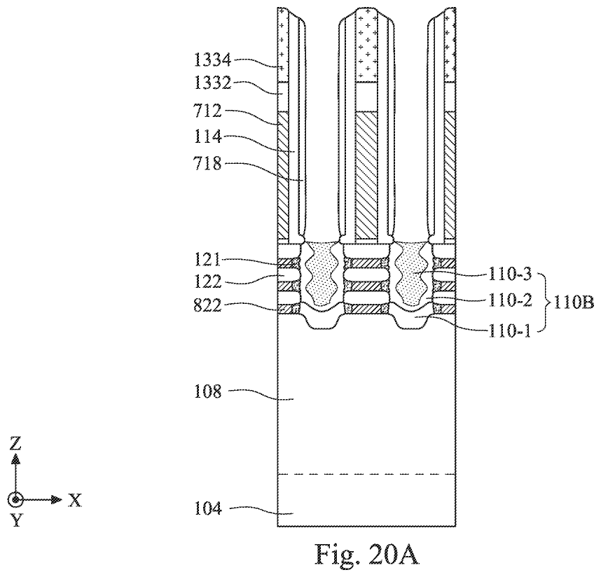

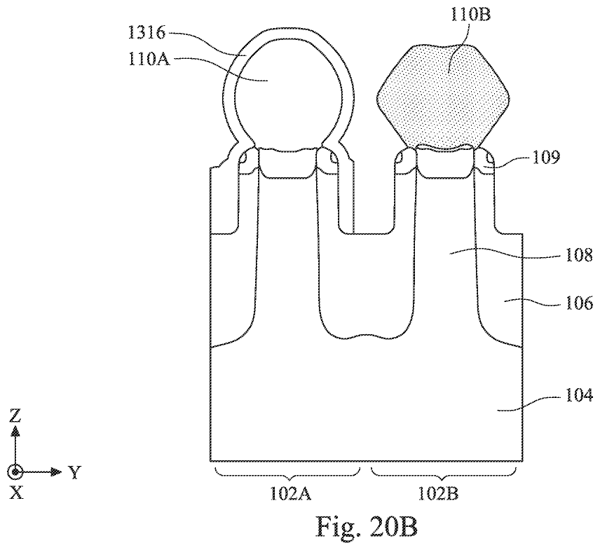

Referring to FIG. 6, in operation 640, a third epitaxial layer is formed on the second epitaxial layer. For example, as shown in FIGS. 19, 20A, and 20B, third epitaxial layer 110-3 can be formed on second epitaxial layer 110-2. In some embodiments, third epitaxial layer 110-3 can be epitaxially grown on (111) growth planes of second epitaxial layer 110-2. Accordingly, slanted dopant clusters 113s can extend along an interface between second epitaxial layer 110-2 and third epitaxial layer 110-3. In some embodiments, third epitaxial layer 110-3 can include silicon germanium with a germanium concentration from about 50 atomic percent to about 80 atomic percent, with any remaining atomic percent being Si. In some embodiments, the germanium concentration in third epitaxial layer 110-3 can be greater than the germanium concentration in second epitaxial layer 110-2. In some embodiments, third epitaxial layers 110-3 can be doped during the epitaxial growth with boron having a concentration in a range from about 5×10²⁰ atoms/cm³ to about 2×10²¹ atoms/cm³. In some embodiments, the dopant concentration in third epitaxial layer 110-3 can be greater than the dopant concentration in second epitaxial layer 110-2 to reduce contract resistance between S/D structures 110 and subsequently-formed S/D contact structures 130. In some embodiments, an anneal process can be performed after the formation of third epitaxial layer 110-3. In some embodiments, horizontal dopant clusters 113h and slanted dopant clusters 113s in second epitaxial layer 110-2 can remain after the anneal process.

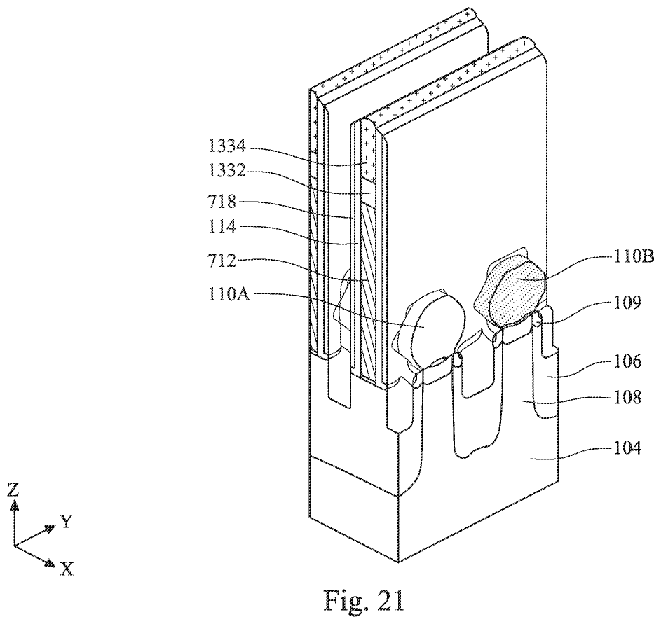

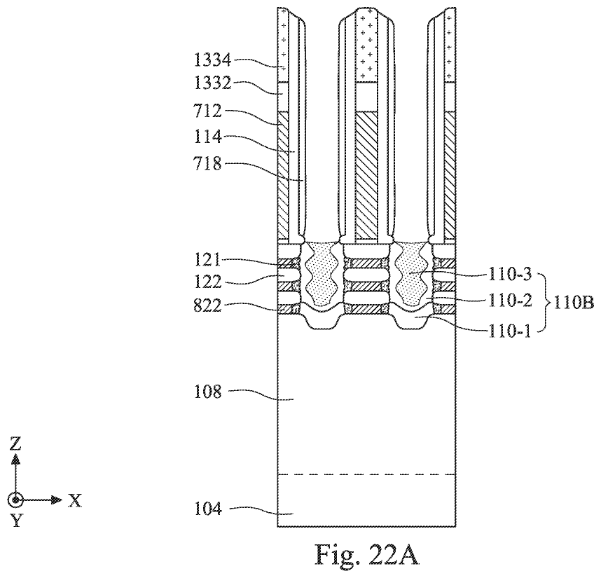

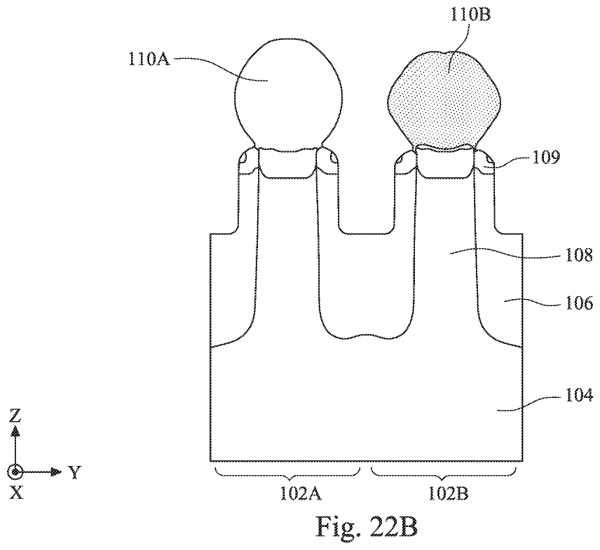

The formation of third epitaxial layer 110-3 can be followed by removal of the dielectric layer 1316, as shown in FIGS. 21, 22A, and 22B. The removal of dielectric layer 1316 can be followed by the formation of ESL 116, the formation of ILD layer 118, replacement of sacrificial gate structures 712 with metal gate structures 112, and the formation of S/D contact structures 130 to form semiconductor device 100 as shown in FIGS. 1-3. These processes are not described in detail for clarity. In some embodiments, as shown in FIGS. 1-3, S/D contact structures 130 can extend into S/D structures 110 and can be in contact with horizontal dopant clusters 113h and/or slanted dopant clusters 113s. In some embodiments, the high dopant concentration in horizontal dopant clusters 113h and slanted dopant clusters 113s can further reduce the contact resistance between S/D contact structures 130 and S/D structures 110.

Various embodiments in the present disclosure provide example methods for forming S/D structures 110 having horizontal dopant clusters 113h in semiconductor device 100. In some embodiments, nanostructures 122 can be formed on substrate 104. S/D structures 110 can be formed on substrate 104 and adjacent to nanostructures 122. In some embodiments, S/D structures 110 can include first epitaxial layer 110-1 on substrate 104, second epitaxial layer 110-2 on first epitaxial layer 110-1 and sidewalls of nanostructures 122, and third epitaxial layer 110-3 on second epitaxial layer 110-2. In some embodiments, second epitaxial layer 110-2 can include horizontal dopant clusters 113h extending along a direction of nanostructures 122. In some embodiments, a first concentration of the dopant in horizontal dopant clusters 113h can be more than about ten times greater than a concentration of the dopant in second epitaxial layer 110-2. In some embodiments, horizontal dopant clusters 113h can extend along an intersection of (111) growth planes of the second epitaxial layer. In some embodiments, second epitaxial layer 110-2 can include slanted dopant clusters 113s along the (111) growth planes of second epitaxial layer 110-2. Horizontal dopant clusters 113h and slanted dopant clusters 113s can reduce etching damage to S/D structures 110, reduce gate-S/D short defects, and improve device performance and yield.

In some embodiments, a semiconductor structure includes a channel structure on a substrate and an epitaxial structure on the substrate and adjacent to the channel structure. The epitaxial structure includes a first epitaxial layer on sidewalls of the channel structure and a second epitaxial layer on the first epitaxial layer. The first epitaxial layer includes a cluster of a dopant extending along a direction of the channel structure.

In some embodiments, a semiconductor device includes first and second channel structures on a substrate and a source/drain (S/D) structure between the first and second channel structures. The S/D structure includes a first epitaxial layer on sidewalls of the first and second channel structures and a second epitaxial layer on the first epitaxial layer. The first epitaxial layer includes a first cluster of a dopant extending from the first channel structure towards the second channel structure.

In some embodiments, a method includes forming a channel structure on a substrate, forming a first epitaxial layer on the substrate and sidewalls of the channel structure, and forming a second epitaxial layer on the first epitaxial layer. The first epitaxial layer includes a cluster of a dopant extending along a direction of the channel structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a channel structure on a substrate; and
an epitaxial structure on the substrate and adjacent to the channel structure, wherein the epitaxial structure comprises:
a first epitaxial layer on sidewalls of the channel structure, wherein the first epitaxial layer comprises a cluster of a dopant extending along a direction of the channel structure; and
a second epitaxial layer on the first epitaxial layer.

2. The semiconductor structure of claim 1, wherein a first concentration of the dopant in the cluster is greater than a second concentration of the dopant in the first epitaxial layer.

3. The semiconductor structure of claim 2, wherein the first concentration is at least ten times greater than the second concentration.

4. The semiconductor structure of claim 2, wherein the first concentration is greater than about 5×10²⁰ atoms/cm³.

5. The semiconductor structure of claim 1, wherein the first epitaxial layer further comprises an additional cluster of the dopant extending along an interface between the first and second epitaxial layers.

6. The semiconductor structure of claim 5, wherein the additional cluster is along a (111) growth plane of the first epitaxial layer and the cluster extends along an intersection of the (111) growth plane and an additional (111) growth plane of the first epitaxial layer.

7. The semiconductor structure of claim 5, further comprising an inner spacer between the channel structure and the epitaxial structure, wherein the additional cluster is in contact with the inner spacer.

8. The semiconductor structure of claim 5, wherein a first concentration of the dopant in the cluster is greater than a second concentration of the dopant in the additional cluster.

9. The semiconductor structure of claim 1, further comprising a contact structure extending into the epitaxial structure, wherein the cluster is in contact with the contact structure.

10. The semiconductor structure of claim 1, wherein the epitaxial structure further comprises an additional epitaxial layer between the first epitaxial layer and the substrate, and wherein a germanium concentration in the first epitaxial layer is greater than a germanium concentration in the additional epitaxial layer and less than a germanium concentration in the second epitaxial layer.

11. A semiconductor device, comprising:
first and second channel structures on a substrate; and
a source/drain (S/D) structure between the first and second channel structures, wherein the S/D structure comprises:
a first epitaxial layer on sidewalls of the first and second channel structures, wherein the first epitaxial layer comprises a first cluster of a dopant extending from the first channel structure towards the second channel structure; and
a second epitaxial layer on the first epitaxial layer.

12. The semiconductor device of claim 11, wherein a first concentration of the dopant in the first cluster is greater than a second concentration of the dopant in the first epitaxial layer.

13. The semiconductor device of claim 12, wherein the first concentration is at least ten times greater than the second concentration.

14. The semiconductor device of claim 11, wherein the first epitaxial layer further comprises a second cluster of the dopant at an interface of the first and second epitaxial layers, and wherein a first concentration of the dopant in the first cluster is greater than a second concentration of the dopant in the second cluster.

15. The semiconductor device of claim 14, wherein an angle between the first and second clusters of the dopant ranges from about 40 degrees to about 70 degrees.

16. The semiconductor device of claim 14, further comprising a contact structure extending into the S/D structure, wherein the first and second clusters are in contact with the contact structure.

17. A method, comprising:
forming a channel structure on a substrate;
forming a first epitaxial layer on the substrate and sidewalls of the channel structure, wherein the first epitaxial layer comprises a cluster of a dopant extending along a direction of the channel structure; and
forming a second epitaxial layer on the first epitaxial layer.

18. The method of claim 17, wherein forming the first epitaxial layer comprises controlling a precursor containing the dopant at a substantially constant flow rate.

19. The method of claim 17, further comprising forming an additional cluster of the dopant at an interface of the first and second epitaxial layers, wherein an angle between the cluster and the additional cluster of the dopant ranges from about 40 degrees to about 70 degrees.

20. The method of claim 17, further comprising forming an additional epitaxial layer on the substrate prior to forming the first epitaxial layer and forming a contact structure in the second epitaxial layer, wherein the cluster is in contact with the contact structure.
